(19) United States
(12) Patent Application Publication
(10) Pub. No.: US 2014/0245101 A1
(43) Pub. Date: Aug. 28, 2014

(54) SEMICONDUCTOR MEMORY

(71) Applicant: KABUSHIKI KAISHA TOSHIBA, Minato-ku (JP)

(72) Inventors: Tokumasa HARA, Kanagawa (JP); Osamu Torii, Tokyo (JP); Yasukazu Kosaki, Kanagawa (JP)

(73) Assignee: KABUSHIKI KAISHA TOSHIBA, Minato-ku (JP)

(21) Appl. No.: 13/956,824

(22) Filed: Aug. 1, 2013

Related U.S. Application Data
(60) Provisional application No. 61/770,360, filed on Feb. 28, 2013.

(51) Int. Cl. H03M 13/29

(52) U.S. Cl. CPC H03M 13/29
USPC 714/758

(57) ABSTRACT

According to one embodiment, a semiconductor memory includes a memory cell unit, an encoding circuit that generates a first parity and a second parity for data, and a decoding circuit that performs error correction by using the data, the first parity, and the second parity, the first parity is generated by using a first generation polynomial for the data, the second parity is generated by using a second generation polynomial for the input data and the first parity, the second generation polynomial is selected based on the first generation polynomial, the data and the first parity is output to the outside, and the second parity is not output to the outside.

### CROSS-REFERENCE TO RELATED APPLICATIONS

This application is based upon and claims the benefit of priority from Provisional Patent Application No. 61/770,360, filed on Feb. 28, 2013; the entire contents of which are incorporated herein by reference.

### FIELD

Embodiments described herein relate generally to a semiconductor memory.

### BACKGROUND

There is NAND flash memory (ECC built-in NAND flash memory) having an ECC function built therein by mounting an error check and correct (ECC) circuit as on-chip.

A parity is written into a memory cell array of an NAND flash memory together with user data.

The ECC circuit performs detection of errors and error correction by using data and a parity read from the memory cell array and outputs user data after the error correction.

In a conventional ECC built-in NAND flash memory, generally, the error correction capability (error-correctable number of bits) of the ECC circuit and the allocation of an inner-page address at which a parity is stored are published as a specification so as to read out the parity to the outside of the NAND flash memory. By reading out the parity to the outside of the NAND flash memory, for example, in a case where an error correction cannot be made by the built-in ECC memory, an error factor can be analyzed using the parity outside the NAND flash memory.

Generally, when the miniaturization of a NAND flash memory progresses, the probability of error in data written into the memory cell array of the NAND flash memory increases. Accordingly, as the miniaturization progresses, the built-in ECC circuit needs an error correction code (ECC) having a capability higher than the correction capability thereof. However, when the correction capability of the error correction code (ECC) is simply strengthened, the allocation of the inner-page address at which the parity is stored and the like change, which are published as the specification, and it is necessary to change the specification. In order to acquire the compatibility with a NAND flash memory of a different generation according to miniaturization, it is preferable that the specification is not changed regardless of the progress of the miniaturization.

### BRIEF DESCRIPTION OF THE DRAWINGS

FIG. 1 is a block diagram that illustrates an example of the configuration of a semiconductor memory according to a first embodiment.

FIG. 2 is a diagram that illustrates an example of the configuration of an ECC circuit according to the first embodiment.

FIG. 3 is a diagram that illustrates an example of the inner-page allocation of a NAND memory cell array according to the first embodiment.

FIG. 4 is a diagram that illustrates an example of a write processing sequence according to the first embodiment.

FIG. 5 is a diagram that illustrates an example of a read processing sequence according to the first embodiment.

FIG. 6 is a diagram that illustrates an example of the inner-page allocation of a NAND memory cell array according to a second embodiment.

FIG. 7 is a diagram that illustrates an example of a write processing sequence according to the second embodiment.

FIG. 8 is a diagram that illustrates an example of a read processing sequence according to the second embodiment.

FIG. 9 is a diagram that illustrates an example of the inner-page allocation of a NAND memory cell array according to a third embodiment.

FIG. 10 is a diagram that illustrates an example of a write processing sequence according to the third embodiment.

FIG. 11 is a diagram that illustrates an example of a read processing sequence according to the third embodiment.

### DETAILED DESCRIPTION

In general, according to one embodiment, a semiconductor memory includes: a memory cell unit; an interface unit that receives a command and data from the outside of the semiconductor memory cell and transmits data to the outside of the semiconductor memory; an encoding circuit that generates a first parity and a second parity for data; and a decoding circuit that performs error correction by using the data, the first parity and the second parity. The first parity is generated using a first generation polynomial for the data, and a second parity is generated using a second generation polynomial for the input data and the first parity, and the second generation polynomial is selected based on the first generation polynomial. The interface unit outputs the data and the first parity to the outside but does not output the second parity to the outside.

Exemplary embodiments of semiconductor memory will be explained below in detail with reference to the accompanying drawings. The present invention is not limited to the following embodiments.

### First Embodiment

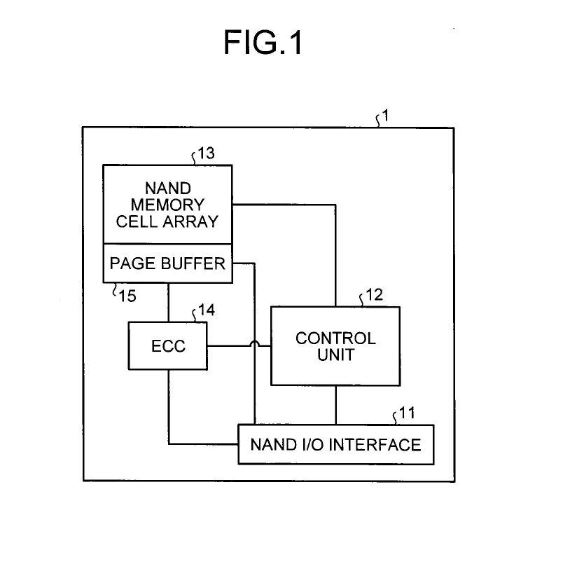

FIG. 1 is a block diagram that illustrates an example of the configuration of a semiconductor memory 1 according to a first embodiment. As illustrated in FIG. 1, the semiconductor memory 1 according to this present embodiment includes a NAND I/O interface 11, a control unit 12, a NAND memory cell array (memory cell unit) 13, an ECC circuit (ECC unit) (abbreviated as ECC in FIG. 1) 14, and a page buffer 15. The semiconductor memory 1 according to this embodiment, as illustrated in FIG. 1, is an ECC built-in memory having the ECC circuit 14 built therein, and, for example, the ECC circuit 14 is mounted as on-chip. The semiconductor memory 1 is configured by a one-chip semiconductor substrate (for example, a silicon substrate), and the NAND I/O interface 11, the control unit 12, the NAND memory cell array (memory cell unit) 13, the ECC circuit 14, and the page buffer 15 are mounted on one chip.

The semiconductor memory 1 according to this embodiment, for example, is connected to a memory controller not illustrated in the figure and, in the case of being instructed to perform writing from the memory controller, receives writing data from the memory controller and stores the received writing data in the NAND memory cell array 13. In the case of being instructed to perform reading from the memory controller, the semiconductor memory 1 according to this embodiment reads data from the NAND memory cell array 13 and outputs the read data to the memory controller.

The NAND I/O interface 11 controls input/output from or to an external device such as a memory controller. In a case where a command such as a write request or a read request is input from the outside, the NAND I/O interface 11 inputs the command to the control unit 12. In a case where user data to be written into the NAND memory cell array 13 is input from the outside, the NAND I/O interface 11 inputs the user data to the ECC circuit 14, and, in a case where read data after error correction is output from the ECC circuit 14, the NAND I/O interface 11 outputs the read data to the outside. The user data is a general term of write target data input from the outside of the semiconductor memory 1. In the user data, a parity generated by the ECC circuit inside the semiconductor memory 1 is not included.

The ECC circuit 14 generates a parity by performing an error correction code (ECC) implementing process based on the user data written in the NAND memory cell array 13. The ECC circuit 14 performs error detection and error correction for the user data and the parity read from the NAND memory cell array 13 and outputs user data after error correction to the NAND I/O interface 11.

The control unit 12 controls the operation of the semiconductor memory 1 based on a command or the like input from the NAND I/O interface 11. More specifically, in a case where a write request is input, the control unit 12 performs control such that user data requested to be written is written at a designated address on the NAND memory cell array 13. The control unit 12 performs control such that the parity generated by the ECC circuit 14 is written into the NAND memory cell array 13 together with the user data. In a case where a read request is input, the control unit 12 performs control such that user data requested to be read and a parity corresponding to the user data are read from the NAND memory cell array 13 and are input to the ECC circuit 14.

The semiconductor memory 1 according to this embodiment generates a parity and stores user data with the parity at the time of storing the user data input as described above in the NAND memory cell array 13, and performs error correction using the user data and the parity and then outputs the user data at the time of reading data. Accordingly, an error correction process is performed for the user data output from the semiconductor memory 1. However, in the ECC built-in memory, the error correction capability of the built-in ECC circuit and the allocation of an inner-page address at which a parity is stored are published as a specification so as to enable a user to use the parity.

Accordingly, in the semiconductor memory 1 according to this embodiment, the parity stored in the NAND memory cell array 13 can be read out to the outside of the semiconductor memory 1 by designating the address of a parity part also as a reading target. In a case where the address of the parity part is designated also as a reading target, the control unit 12 performs control such that not only the user data after error correction but also the parity is output through the NAND I/O interface 11.

In order to acquire the compatibility with a NAND flash memory of a different generation according to miniaturization, it is preferable that the specification is not changed regardless of the progress of the miniaturization. Meanwhile, for example, when the generation progresses, the built-in ECC circuit needs an error correction code (ECC) having a capability higher than the correction capability thereof. In this embodiment, by generating a parity using a multi-stage error correction system, the error correction capability can be changed without changing the specification disclosed to a user (for example, an enterprise developing a product using a NAND flash memory).

The multi-stage error correction system according to this embodiment represents a multi-stage error correction system employing a method of selecting a generation polynomial (a generation polynomial used for an i-th parity (i is an integer of one or more and n or less) is selected based on a generation polynomial used for generating a 1st parity to an (i−1)-th parity) disclosed in the Japanese patent application JP 2012-061692 A. The disclosures of Japanese patent application JP 2012-061692 A is hereby incorporated by reference.

In JP 2012-061692 A, it is disclosed that a first parity that is a parity of a first step is generated by using a generation polynomial G₁(x), a second parity that is a parity of a second step is generated by using a generation polynomial G₂(x), an n-th parity that is a parity of an n-th step is generated by using a generation polynomial Gₙ(x), and a generation polynomial Gᵢ(x) is generated based on G₁(x), G₂(x), . . . , Gᵢ₋₁(x).

In this embodiment, as the multi-stage error correction system disclosed in JP 2012-061692 A, an example where external parities #1, #2, . . . , #n that are parities (hereinafter, referred to as external parities) for the 1st, 2nd, . . . , n-th parities are generated, an example where an external parity is not used, an example where a stage in which an external parity is used and a stage in which an external parity is not used are mixed are described. In this embodiment, an example where a stage in which an external parity is used and a stage in which an external parity is not used are mixed will be described.

Hereinafter, in this embodiment, an example will be described in which the number of stages in the multi-stage error correction system is 2 (n=2), and an external parity is added to a parity of the second stage. In this embodiment, parity #1 represents a parity of the first stage (a parity that is generated by using the generation polynomial G₁(x) with user data being set as input data) in the multi-stage error correction system, parity #2 represents a parity of the second stage (a parity that is generated by using the generation polynomial G₂(x) with user data and parity #1 being set as input data) in the multi-stage error correction system, and parity #3 represents a parity (external parity) of parity #2.

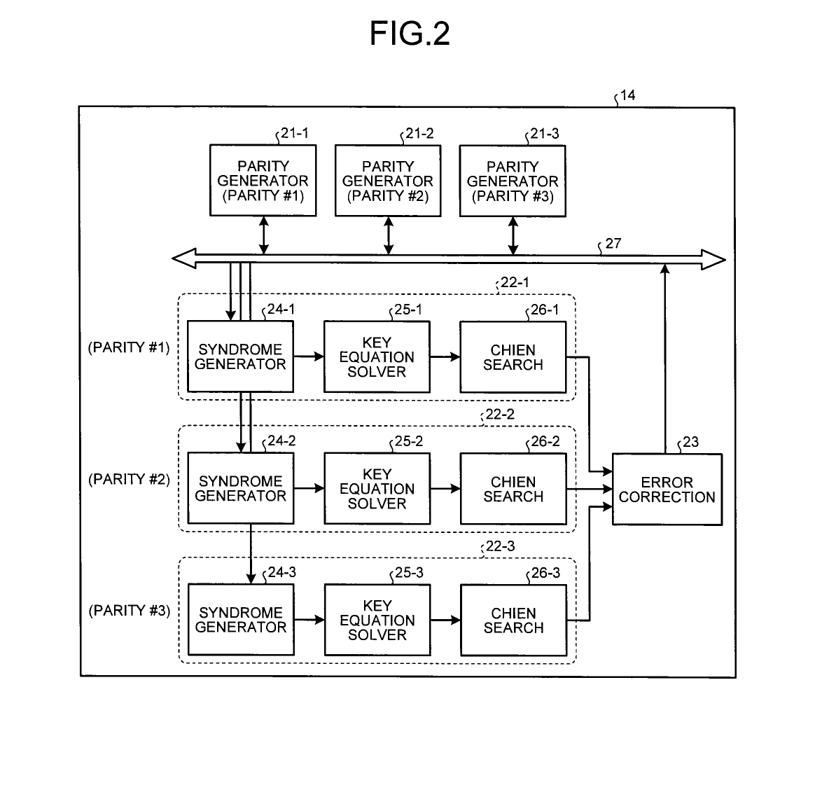

FIG. 2 is a diagram that illustrates an example of the configuration of the ECC circuit 14 according to this embodiment. The ECC circuit 14 according to this embodiment includes parity generators 21-1 to 21-3, decoding units 22-1 to 22-3, an error correction unit 23, and a data bus 27. The decoding unit 22-j (here, j=1, 2, 3) includes a syndrome generator 24-j, a key equation solver 25-j, and a Chien search unit 26-j.

The parity generator 21-1 performs an error correction code (ECC) implementing process using the generation polynomial G₁(x) with user data being set as input data, thereby generating parity #1. The parity generator 21-2 performs an error correction code (ECC) implementing process using the generation polynomial G₂(x) with the user data and parity #1 being set as input data, thereby generating parity #2. The generation polynomial G₁(x) and the generation polynomial G₂(x) are the generation polynomials of the first and second stages in the multi-stage error correction system. The parity generator 21-3 generates parity #3 using an arbitrary generation polynomial with parity #2 being set as input data. The generated parities #1, #2, and #3 are output to the data bus 27.

The decoding unit 22-1 performs a decoding process (error detection and the specification of an error position) by using the user data and parity #1 read from the NAND memory cell array 13. The decoding unit 22-2 performs a decoding process by using the user data, parity #1, and parity #2 read from the NAND memory cell array 13. The decoding unit 22-2 performs a decoding process based on parity #2 and parity #3 read from the NAND memory cell array 13.

The syndrome generator 24-j forms a syndrome based on input data and inputs the formed syndrome to the key equation solver 25-j. The key equation solver 25-j derives an error position polynomial by using the syndrome and determines the number of error bits. In a case where the number of error bits is larger than one, the key equation solver 25-j inputs the error position polynomial to the Chien search 26-j. The Chien search 26-j specifies the position of an error bit based on the input error position polynomial.

The error correction unit 23 corrects for an error by inverting bit data in accordance with the position of the error bit that is output from the Chien search 26-j.

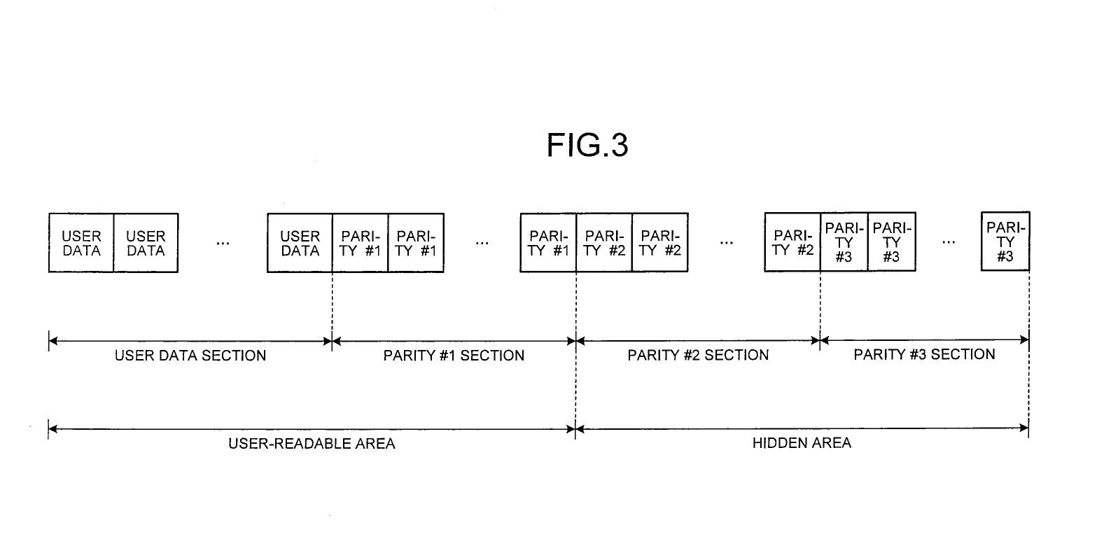

FIG. 3 is a diagram that illustrates an example of the inner-page allocation of the NAND memory cell array 13 according to this embodiment. In the NAND memory, writing is performed in recording units called pages. In this embodiment, user data stored in one page is divided into a plurality of sectors (unit data). One sector, for example, is set as 512 bytes, and, for example, one page is configured to include user data of 8 sectors. Hereinafter, although an example will be described in which one page includes user data of eight sectors, and one sector is 512 bytes, the size of the sector and the number of sectors included in one page are not limited to those described in this example. In this embodiment, the error correction code (ECC) implementing process is performed in units of sectors.

As illustrated in FIG. 3, in this embodiment, the page data of one page is configured by a user data section, a parity #1 section, a parity #2 section, and a parity #3 section. The user data section is configured by user data of 8 sectors. The parity #1 section is configured by eight parities #1 corresponding to the user data of 8 sectors. The parity #2 section is configured by eight parities #2 corresponding to the user data of 8 sectors. The parity #3 section is configured by eight parities #3 corresponding to the user data of 8 sectors.

In this embodiment, the user data section and the parity #1 section are stored in a user readable area, and the address allocation of this area and the error correction capability of parity #1 are disclosed to a user as a specification. On the other hand, the parity #2 section and the parity #3 section are stored in a hidden area. The hidden area has an address that is not disclosed to a user and is an unreadable area for the user. The inner-page allocation illustrated in FIG. 3 is an example, the inner-page allocation is not limited to the example illustrated in FIG. 3, and the user data and the allocation position of parity #1 may be disclosed to the user, and parities #2 and #3 may be stored in the hidden area. Here, the error correction capability represents the number of error correctable bits. In a case where the error correction capability of parity #1 is n bits, error correction can be performed by using parity #1 up to n bits of error bits included in the user data and parity #1. In a case where the error correction capability of parity #2 is m bits, error correction can be performed by using parity #2 up to m bits of error bits included in the user data, parity #1, and parity #2. By employing the above-described multi-stage error correction system, in a case where the error correction capability of parity #1 is n bits and the error correction capability of parity #2 is m bits, by using parity #1 and parity #2, error correction can be performed up to n+m bits of error bits included in the user data, parity #1, and parity #2. In other words, the error correction capability acquired by combining parity #1 and parity #2 is n+m bits.

In this embodiment, in a case where both parity #1 and parity #2 are used, the error correction capability is determined to be an error correction capability that is necessary for correcting the error of the NAND memory cell array 13. Accordingly, the error correction capability of parity #1 disclosed to a user as the specification may be arbitrarily determined without being dependent on the error correction capability that is necessary for correcting the error of the NAND memory cell array 13. After the size of parity #1 is determined, the size of parity #2 is determined such that the error correction capability of a case where both parity #1 and parity #2 are used is an error correction capability capable of correcting the error of the NAND memory cell array 13. The size of parity #3 is determined based on an error correction capability for which the error of parity #2 is corrected with a sufficiently high probability.

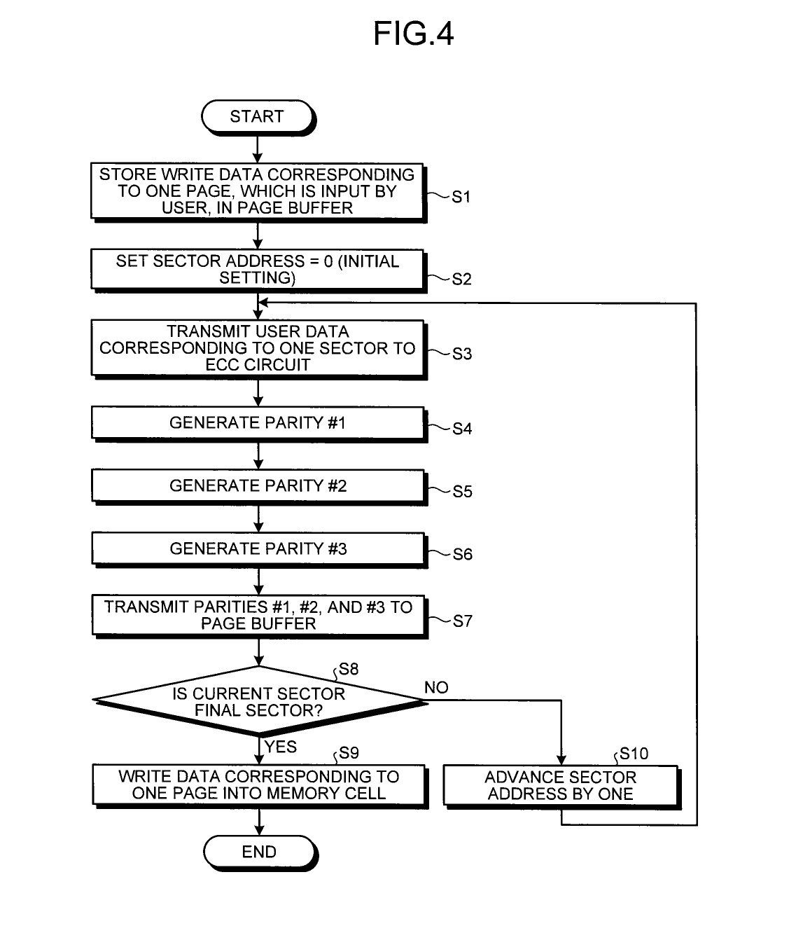

FIG. 4 is a diagram that illustrates an example of a write processing sequence according to this embodiment. FIG. 4 illustrates the sequence in a case where writing corresponding to one page is performed. The control unit 12 performs control such that write data (user data) corresponding to one page, which is input by a user, is stored in a page buffer in Step S1. Under the control of the control unit 12, the user data corresponding to one page, which is input from the NAND I/O interface 11, is stored in the page buffer 15.

Next, the control unit 12 sets the address of a sector (sector address), which is a processing target, to zero as an initial setting in Step S2. Here, for example, the sector addresses of the sectors of the user data of the user data section illustrated in FIG. 3 are sequentially set to 0, 1, 2, . . . , 7 from the left end. The control unit 12 performs control such that user data corresponding to one sector is transmitted from the page buffer to the ECC circuit 14, and the user data corresponding to one sector is transmitted from the page buffer to the ECC circuit 14 in Step S3.

The ECC circuit 14 generates parity #1 based on the received user data corresponding to one sector in Step S4. Next, the ECC circuit 14 generates parity #2 based on the user data corresponding to one sector and parity #1 in Step S5. The ECC circuit 14 generates parity #3 based on parity #2 in Step S6.

The control unit 12 instructs the ECC circuit 14 to transmit parities #1, #2, and #3 to the page buffer in Step S7. Next, the control unit 12 determines whether the sector address of the current processing target is the sector address of the final sector (in a case where one page includes 8 sectors, sector address=7) in Step S8. In the case of the final sector address (Yes in Step S8), the control unit 12 writes the user data corresponding to one page, parity #1, parity #2, and parity #3 into the memory cell (the NAND memory cell array 13) in accordance with the inner page allocation illustrated in FIG. 3 in Step S9. On the other hand, in a case where the sector address of the current processing target is not the sector address of the final sector (No in Step S8), the sector address advances by one in Step S10, and the process is returned to Step S3.

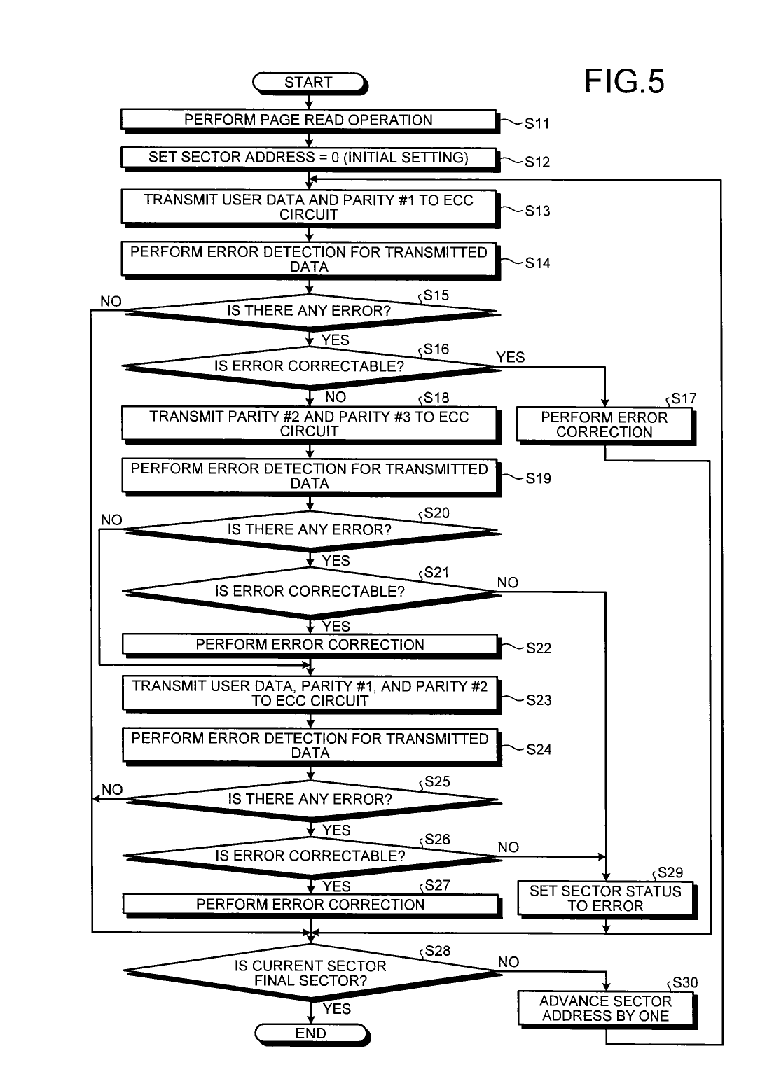

FIG. 5 is a diagram that illustrates an example of a read processing sequence according to this embodiment. First, the control unit 12 performs a read operation of one page from the NAND memory cell array 13 in Step S11. Next, the control unit 12 sets the sector address of the processing target sector to zero as an initial setting in Step S12. The control unit 12 performs control such that the user data of the sector address of the processing target and parity #1 are transmitted to the ECC circuit 14 in Step S13. In the ECC circuit 14, the encoding unit 22-1 performs error detection by using the transmitted data (the user data and parity #1) in step S14.

The encoding unit 22-1 determines whether or not there is an error based on a result of the error detection in Step S15. More specifically, the key equation solver 25-1 determines whether or not the number of detected error bits is one or more. In a case where there is an error (Yes in Step S15), it is determined whether or not the error is correctable in Step S16. More specifically, it is determined whether or not the number of detected errors is the number of correctable errors or less. In a case where the error is correctable (Yes in Step S16), the ECC circuit 14 performs error correction in Step S17, and the process proceeds to Step S28. In Step S17, more specifically, the Chien search unit 26-1 specifies an error position, and the error correction unit 23 corrects the error based on the specified error position.

In Step S28, the control unit 12 determines whether or not the sector address of the current processing target is the sector address of a final sector (in a case where one page includes 8 sectors, the sector address=7) in Step S28. In a case where the sector address of the current processing target is the sector address of the final sector (Yes in Step S28), the control unit 12 outputs user data (in a case where the control unit 12 is instructed to read parity #1 from the user as well, parity #1 is included) corresponding to one page, and the process ends. On the other hand, in a case where the sector address of the current processing target is not the sector address of the final sector (No in Step S28), the control unit 12 advances the sector address by one address in Step S30, and the process is returned to Step S13.

On the other hand, in a case where the error is determined not to be correctable in Step S16 (No in Step S16), the control unit 12 transmits parity #2 and parity #3 to the ECC circuit 14 in Step S18. In the ECC circuit 14, the encoding unit 22-3 performs error detection by using the transmitted data (parity #2 and parity #3) in Step S19.

The encoding unit 22-3 determines whether or not there is an error based on a result of the error detection in Step S20. More specifically, the key equation solver 25-3 determines whether or not the number of detected error bits is one or more. In a case where there is an error (Yes in Step S20), it is determined whether or not the error is correctable in Step S21. In a case where the error is correctable (Yes in Step S21), the ECC circuit 14 performs error correction in Step S22. More specifically, the Chien search unit 26-3 specifies an error position, and the error correction unit 23 corrects the error based on the specified error position.

Next, the control unit 12 transmits the user data, parity #1, and parity #2 (after error correction) to the ECC circuit 14 in Step S23. In the ECC circuit 14, the encoding unit 22-2 performs error detection by using the transmitted data (the user data, parity #1, and parity #2) in Step S24.

The encoding unit 22-2 determines whether or not there is an error based on a result of the error detection in Step S25. More specifically, the key equation solver 25-2 determines whether or not the number of detected error bits is one or more. In a case where there is an error (Yes in Step S25), it is determined whether or not the error is correctable in Step S26. In a case where the error is correctable (Yes in Step S26), the ECC circuit 14 performs error correction in Step S27, and the process proceeds to Step S28. More specifically, in Step S27, the Chien search unit 26-2 specifies an error position, and the error correction unit 23 corrects the error based on the specified error position.

On the other hand, in a case where it is determined that the error is not correctable in Step S21 (No in Step S21), the control unit 12 sets a sector status representing the error correction status of the sector to error in Step S29, and the process proceeds to Step S28. In a case where it is determined that the error is not correctable in Step S26 (No in Step S26), the control unit 12 sets a sector status representing the error correction status of the sector to error in Step S29, and the process proceeds to Step S28.

In a case where it is determined that there is no error in Steps S15 and S25 (No in Step S15 and No in Step S25), the process proceeds to Step S28. In a case where it is determined that there is no error in Step S20 (No in Step S20), the process proceeds to Step S23.

As above, in this embodiment, the multi-stage error correction system is employed, information relating to the parity of the first step is disclosed to the user, and the storage areas of parities of the second and subsequent steps are not disclosed to the user. Accordingly, the error correction capability that is actually necessary can be determined without being dependent on the specification disclosed to the user. For example, it is assumed that parity #1 has an error correction capability of four bits, and parity #2 has an error correction capability of four bits. While an error correction capability of four bits is acquired by using only parity #1, an error correction capability of 8 bits is acquired by using parity #2 together.

In this embodiment, in a case where the number of errors is small at the time of reading data, the decoding process of the first step using parity #1 is performed, and the decoding process of the second step does not need to be performed. Accordingly, the processing speed can be improved to be higher than that of a case where one parity having a high error correction capability is generated while the number of errors is small.

By configuring as such, even in a case where the error correction capability needs to be raised after the specification relating to parity #1 is disclosed to the user, by changing the error correction capability of parity #2, the whole error correction capability may be changed without changing the disclosed specification.

### Second Embodiment

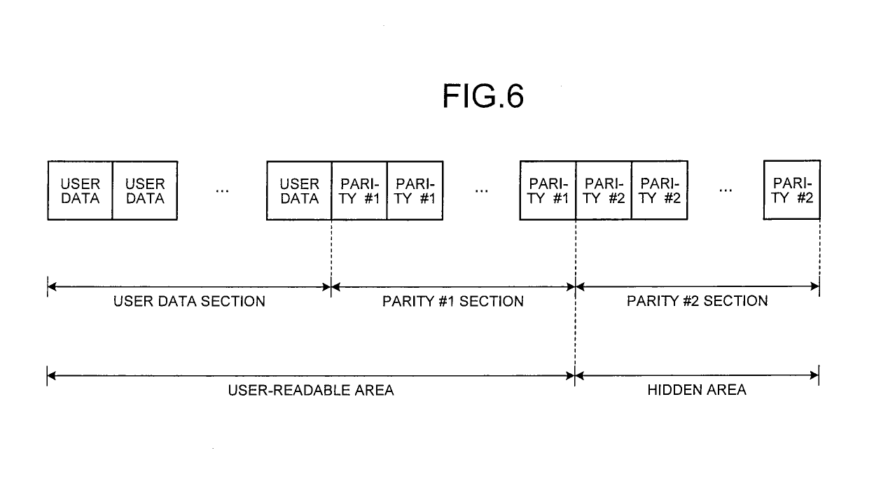

FIG. 6 is a diagram that illustrates an example of the inner-page allocation of a NAND memory cell array 13 according to a second embodiment. The configuration of a semiconductor memory 1 according to this embodiment is the same as that of the first embodiment except that the parity generator 21-3 and the decoding unit 22-3 as the internal configuration of the ECC circuit 14 are removed. Description of parts that are the same as those of the first embodiment will not be presented, and parts different from those of the first embodiment will be described.

In the first embodiment, when a decoding process is performed using parity #2, on the premise that an error is not included in parity #2, the processing speed can be increased, and accordingly, parity #3, which is an external parity of parity #2, is generated.

Generally, since the size of parity #2 is smaller than that of the user data, the probability of an error occurring is negligible. From this, in this embodiment, parity #3 is not generated. As illustrated in FIG. 6, the inner-page allocation of this embodiment is the same as that of the first embodiment except that the parity #3 unit is not included.

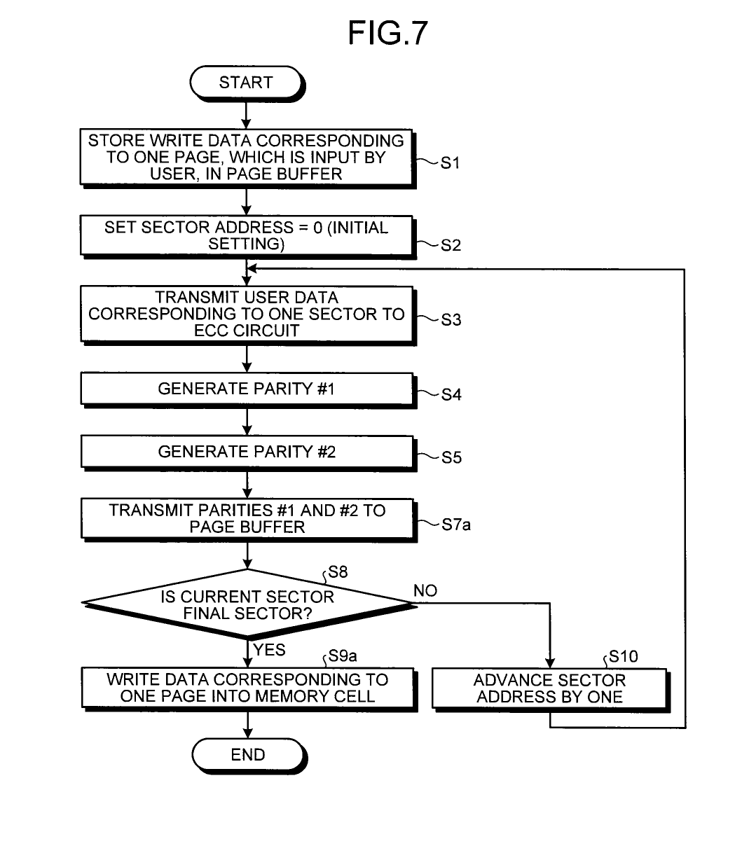

FIG. 7 is a diagram that illustrates an example of a write processing sequence according to this embodiment. Steps S1 to S5 are the same as those of the first embodiment. After Step S5, the control unit 12 instructs the ECC circuit 14 to transmit parities #1 and #2 to the page buffer in Step S7a. Step S8 is the same as that of the first embodiment.

In a case where the sector address of the current processing target is the sector address of the final sector in Step S8 (Yes in Step S8), the control unit 12 writes user data corresponding to one page, parity #1, and parity #2, which is data on the page buffer, into the memory cell (NAND memory cell array 13) in accordance with the inner-page allocation illustrated in FIG. 6 in Step S9a. On the other hand, in a case where the sector address of the current processing target is not the sector address of the final sector in Step S8 (No in Step S8), similarly to the first embodiment, the process of Step S10 is performed, and the process is returned to Step S3.

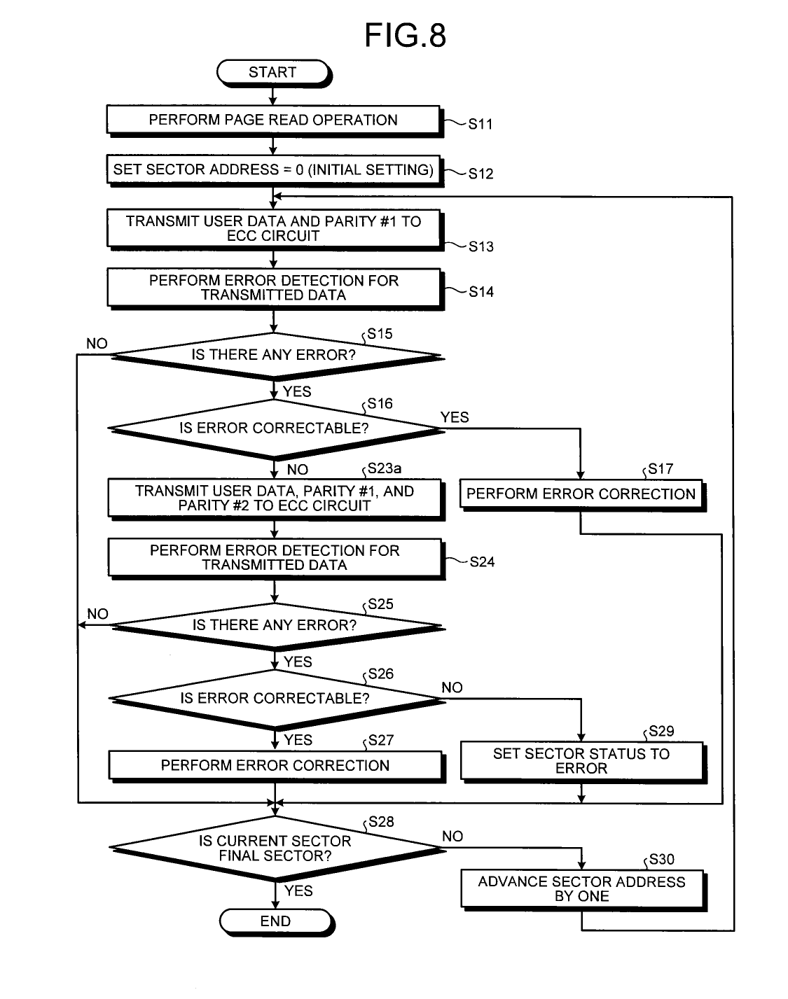

FIG. 8 is a diagram that illustrates an example of a read processing sequence according to this embodiment. Steps S11 to S17 and S24 to S30 are the same as those of the first embodiment. In a case where the error is determined not to be correctable in Step S16 (No in Step S16), the control unit 12 transmits the user data, parity #1, and parity #2 (error is not corrected) to the ECC circuit 14 in Step S23a.

As above, in this embodiment, since the external parity of the parity of the second step is not used, the processing speed of a write operation can be higher than that of the first embodiment, and the configuration of the ECC circuit 14 can be simplified, whereby the parity occupancy rate in the NAND memory cell array 13 can decrease.

### Third Embodiment

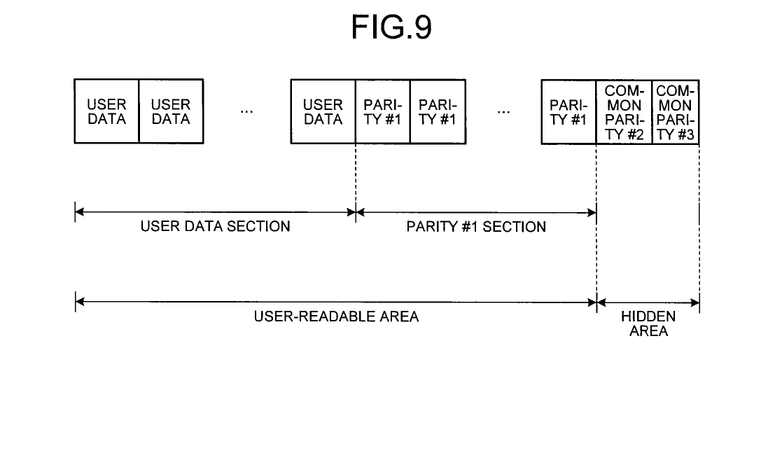

FIG. 9 is a diagram that illustrates an example of the inner-page allocation of a NAND memory cell array 13 according to a third embodiment. The configuration of a semiconductor memory 1 according to this embodiment is the same as that of the first embodiment. Description of parts that are the same as those of the first embodiment will not be presented, and parts different from those of the first embodiment will be described.

In this embodiment, as the multi-stage error correction system, a multigrain multi-stage error correction system is applied. The multigrain multi-stage error correction system, as disclosed in U.S. Ser. No. 13/724,337, is a system in which a generation polynomial used for the generation of a parity in each step is the same as that of the multi-stage error correction system, and the numbers (sizes) of data pieces that become the base of the generation of the parity for each step are different from each other. The disclosures of the US patent application of U.S. Ser. No. 13/724,337 are hereby incorporated by reference.

In this embodiment, while parity #1 is generated for each sector, similarly to the first embodiment, parity #2 is generated for all the sectors included in one page. Parity #3 is a parity of parity #2. Accordingly, parities #2 and #3 are parities that are common to all the sectors included in one page, and, as illustrated in FIG. 9, the area of parity #2 and parity #3 has a size corresponding to one sector, and the parity area can be configured to be smaller than that of the first embodiment.

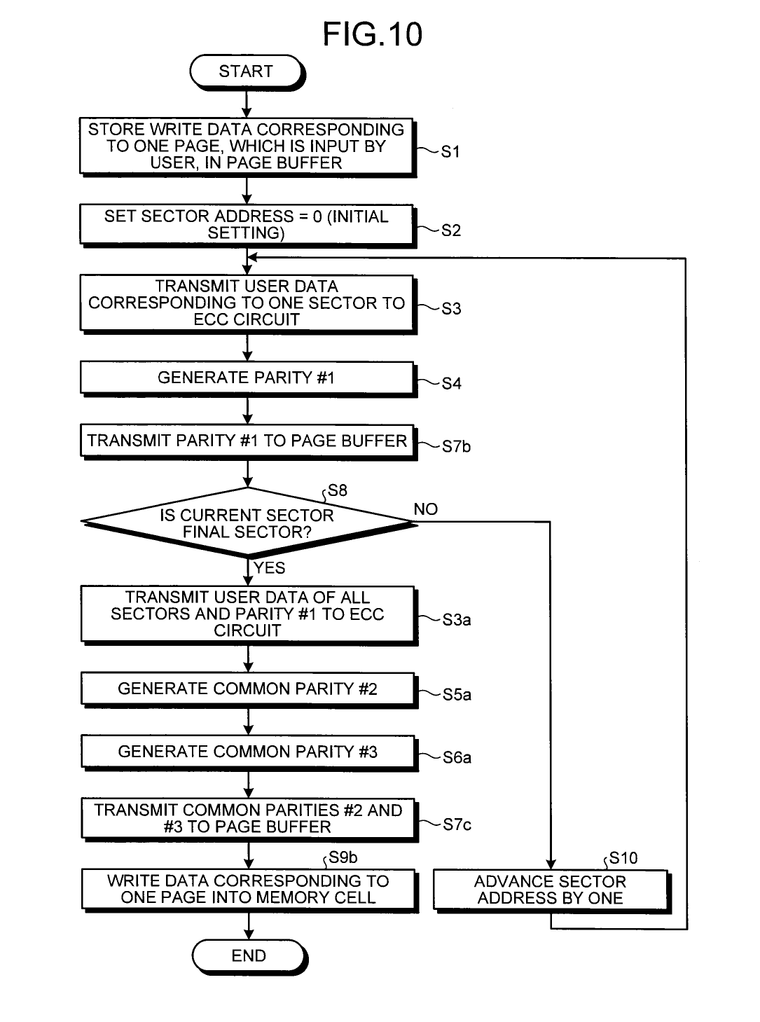

FIG. 10 is a diagram that illustrates an example of a write processing sequence according to this embodiment. Steps S1 to S4 are the same as those of the first embodiment. After Step S4, the control unit 12 instructs the ECC circuit 14 to transmit parity #1 to the page buffer in Step S7b. Step S8 is the same as that of the first embodiment.

In a case where the sector address of the current processing target is the sector address of the final sector in Step S8 (Yes in Step S8), the control unit 12 performs control such that user data of all the sectors corresponding to one page and parity #1 are transmitted to the ECC circuit 14 in Step S3a. Then, the ECC circuit 14 generates parity #2 (common parity #2) based on the transmitted data (the user data of all the sectors corresponding to one page and parity #1) in Step S5a. Next, the ECC circuit 14 generates parity #3 (common parity #3) based on the common parity #2 in Step S6a. The control unit 12 instructs the ECC circuit 14 to transmit the common parities #2 and #3 to the page buffer in Step S7c. Next, the control unit 12 writes data stored in the page buffer into the memory cell (NAND memory cell array 13) in accordance with the inner-page allocation illustrated in FIG. 9 in Step S9b. In a case where the sector address of the current processing target is not the sector address of the final sector in Step S8 (No in Step S8), similarly to the first embodiment, the process of Step S10 is performed, and the process is returned to Step S3.

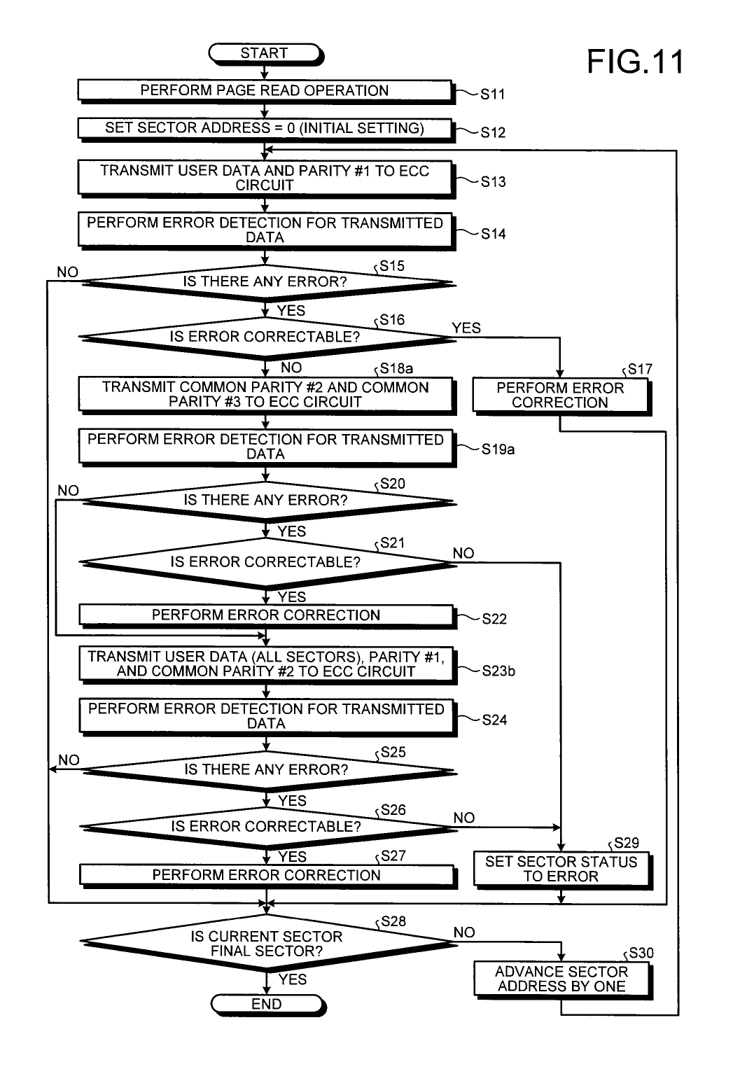

FIG. 11 is a diagram that illustrates an example of a read processing sequence according to this embodiment. Steps S11 to S17 are the same as those of the first embodiment. In a case where the error is determined not to be correctable in Step S16 (No in Step S16), the control unit 12 transmits the common parity #2 and the common parity #3 to the ECC circuit 14 in Step S18a. In the ECC circuit 14, the decoding unit 22-3 performs error detection by using the transmitted data (the common parities #2 and #3) in Step S19a. Steps S20 to S22 are the same as those of the first embodiment.

After Step S22, the control unit 12 transmits the user data of all the sectors included in one page, parity #1, and the common parity #2 (after error correction) to the ECC circuit 14 in Step S23b. Steps S24 to S30 are the same as those of the first embodiment.

Generally, since the common parity #2 is data of a small amount and has a small size, the probability of error occurring is negligible. Accordingly, similarly to the second embodiment, the common parity #3 may not be generated.

In the embodiments described above, while the NAND flash memory has been described as a non-volatile memory, the non-volatile memory is not limited thereto and may be applied to another non-volatile memory device of which error is required to be corrected.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory comprising:
a memory cell unit;
an interface unit that receives a command and data from the outside of the semiconductor memory and transmits data to the outside of the semiconductor memory;
an encoding circuit that generates a first parity and a second parity for data, the first parity being generated using a first generation polynomial for data and the second parity being generated using a second generation polynomial for the data and the first parity, and the second generation polynomial being selected based on the first generation polynomial; and
a decoding circuit that performs error correction by using the data, the first parity, and the second parity,
wherein the interface unit outputs the data and the first parity to the outside of the semiconductor memory and does not output the second parity to the outside of the semiconductor memory.

2. The semiconductor memory according to claim 1, wherein the decoding circuit performs a first error correction process by using the first parity and the data, and performs a second error correction process by using the first parity, the second parity and the data in a case error cannot be corrected by the first error correction process.

3. The semiconductor memory according to claim 1, wherein the encoding circuit additionally generates a third parity by using a third generation polynomial for the second parity.

4. The semiconductor memory according to claim 3, wherein the decoding circuit performs a first error correction process by using the first parity and the data, and, in a case error cannot be corrected by the first error correction process, performs a second error correction process by using the second parity and the third parity and performs a third error correction process by using the data, the first parity and the second parity after the second error correction process.

5. The semiconductor memory according to claim 4, wherein a sum of an error correction capability of the first parity and an error correction capability of the second parity is an error correction capability of the third error correction process using the data, the first parity, and the second parity.
